(19) United States
(12) Patent Application Publication
(10) Pub. No.: US 2012/0037901 A1
(43) Pub. Date: Feb. 16, 2012

(54) OXIDE SEMICONDUCTOR

(75) Inventors: Kiyotaka Mori, Cambridge (GB); Henning Sirringhaus, Cambridge (GB); Kulbinder Kumar Banger, Cambridge (GB); Rebecca Lorenz Peterson, Cambridge (GB)

(73) Assignees: CAMBRIDGE ENTERPRISE LTD., Cambridgeshire (UK); PANASONIC CORPORATION, Osaka (JP)

(21) Appl. No.: 13/265,254

(22) PCT Filed: Apr. 24, 2009
(86) PCT No.: PCT/GB2009/001037

§ 371 Date: Oct. 19, 2011

(51) Int. Cl. H01L 29/12; H01B 1/08; H01L 21/20

(52) U.S. Cl. 257/43; 438/104; 252/519.5; 252/520.1; 252/518.1; 257/E29.068; 257/E21.09

(57) ABSTRACT

The present invention provides highly-stable oxide semiconductors which make it possible to provide devices having an excellent stability. The oxide semiconductor according to the present invention is an amorphous oxide semiconductor including at least one of indium (In), zinc (Zn), and Tin (Sn) and at least one of an alkaline metal or an alkaline earth metal having an ionic radius greater than that of gallium (Ga), and oxygen.

### TECHNICAL FIELD

The present invention relates to oxide semiconductors, and in particular to amorphous oxide semiconductors.

### BACKGROUND ART

Recently, amorphous oxide semiconductors have attracted attention. Such amorphous oxide semiconductors are represented by In—Ga—Zn—O oxide semiconductors (IGZO) as semiconductor layers for the next-generation field-effect thin-film transistors (TFTs). Since most of such semiconductors are amorphous materials and have excellent uniformity, they are materials which can achieve a mobility of 3-20 cm²/Vs required for high-performance liquid crystals and organic ELs (electro-luminescences). For example, the following Patent References 1 to 3 disclose transistors in which IGZOs are used as their channel layers. In addition, it has been reported that TFTs in which IGZOs are used as their base materials achieved stable TFT characteristics and excellent ΔVt required for TFTs for televisions.

[Patent Reference 1] Japanese Unexamined Patent Application Publication No. 2006-165529

[Patent Reference 2] Japanese Unexamined Patent

Application Publication No. 2007-73705

[Patent Reference 3] Japanese Unexamined Patent Application Publication No. 2007-281409

### DISCLOSURE OF INVENTION

### Problems that Invention is to Solve

In oxide semiconductors such as IGZOs including at least one of indium (In) and zinc (Zn), In or Zn transports electrons, and gallium (Ga) keeps the stability of materials by preventing loss of oxygen (O) inside the oxide semiconductors. However, Ga cannot sufficiently prevent loss of oxygen in such oxide semiconductors. Thus, for example, in a transistor such as a field-effect transistor (FET) in which an IGZO is used as its channel layer, loss of oxygen causes a change in the carrier density of the channel layer, resulting in a change in the transistor characteristics such as a threshold voltage Vt. This makes it impossible to obtain devices having stable characteristics.

In view of this problem, the present invention has an object of providing highly-stable oxide semiconductors which make it possible to manufacture devices having an excellent stability.

### MEANS TO SOLVE THE PROBLEMS

In order to achieve the above object, the oxide semiconductor according to the present invention including: at least one of indium (In), zinc (Zn), and Tin (Sn); at least one of an alkaline metal and an alkaline earth metal; and oxygen.

The oxide semiconductor proposed in this invention contains at least one of an alkaline metal or an alkaline earth metal having an oxygen affinity higher than that of Ga. Thus, it becomes possible to achieve highly-stable oxide semiconductors with which devices capable of sufficiently preventing loss of oxygen and thus having an excellent stability can be achieved.

In addition, since such alkaline metal and alkaline earth metal have a higher oxygen affinity, which tends to have a larger change of free energy for the formation of an oxide, further oxidation can be prevented. Thus, it also becomes possible to achieve highly-stable oxide semiconductors which can prevent unstability in carrier density due to loss of oxygen vacancy.

Here, preferably, the oxide semiconductor is amorphous. In addition, preferably, the above-mentioned at least one of the alkaline metal and the alkaline earth metal has an ion radius which is greater than an ion radius of gallium (Ga).

In this way, oxide semiconductors contain at least one of an alkaline metal and an alkaline earth metal which becomes amorphous more easily than one contains just Ga. Therefore, it becomes possible to achieve oxide semiconductors having an excellent uniformity and stability which are achieved by having no or less of a grain boundary associated with a crystalline phase.

In addition, the present invention is implemented as a field-effect transistor including a channel layer having an oxide semiconductor made of: at least one of indium (In), zinc (Zn), and Tin (Sn); at least one of an alkaline metal and/or an alkaline earth metal; and oxygen.

In this way, the channel layer is made of an oxide semiconductor added or associated with at least one of an alkaline metal and/or an alkaline earth metal. In another word, the oxide semiconductor material is alloyed with at least one of an alkaline metal and/or an alkaline earth metal. Accordingly, loss of oxygen in the channel layer is sufficiently prevented. This prevents a change in the carrier density of the channel layer due to loss of oxygen in the use of the field-effect transistor, and prevents the resulting change in the transistor characteristics such as a threshold voltage Vt. As the result, it becomes possible to achieve field-effect transistors (FETs) having an excellent stability.

### EFFECTS OF THE INVENTION

The present invention makes it possible to achieve highly-stable oxide semiconductors, thereby achieving devices having an excellent stability. In addition, the present invention makes it possible to achieve oxide semiconductors having a high uniformity.

### BRIEF DESCRIPTION OF DRAWINGS

These and other objects, advantages and features of the invention will become apparent from the following description thereof taken in conjunction with the accompanying drawings that illustrate a specific Embodiment of the invention. In the Drawings:

FIG. 1 is a cross-sectional view showing the structure of a field-effect transistor of an Example in an Embodiment according to the present invention;

FIG. 2A is a diagram showing variations in the mobility in In—Sr—Zn—O oxide semiconductors each having a different composition ratio of In₂O₃:SrO:ZnO;

FIG. 2B is a diagram showing variations in the On/Off ratios of the corresponding field-effect transistors each having a different composition ratio of In₂O₃:SrO:ZnO;

FIG. 3 is a diagram showing variations in the mobility in In—Sr—Zn—O oxide semiconductors in their formation each containing a different amount of SrO added thereto;

FIG. 4 is a diagram showing variations in the threshold voltages of field-effect transistors each containing a different material in its channel layer;

FIG. 5 is a diagram showing the relationship between value β and −ΔG;

FIG. 6A is a diagram showing a variation in the drain current and the mobility in a field-effect transistor when gate-source voltages are changed;

FIG. 6B is a diagram showing a variation in the drain current and the mobility in a field-effect transistor when gate-source voltages are changed;

FIG. 6C is a diagram showing a variation in the drain current and the mobility in a field-effect transistor when gate-source voltages are changed;

FIG. 6D is a diagram showing a variation in the drain current and the mobility in a field-effect transistor when gate-source voltages are changed;

FIG. 6E is a diagram showing a variation in the drain current and the mobility in a field-effect transistor when gate-source voltages are changed;

FIG. 7A is a diagram showing a variation in the drain current and the mobility in a field-effect transistor when gate-source voltages are changed;

FIG. 7B is a diagram showing a variation in the drain current and the mobility in a field-effect transistor when gate-source voltages are changed;

FIG. 7C is a diagram showing a variation in the drain current and the mobility in a field-effect transistor when gate-source voltages are changed;

FIG. 7D is a diagram showing a variation in the drain current and the mobility in a field-effect transistor when gate-source voltages are changed;

FIG. 8 is a diagram showing a variation in the drain current and the mobility in a field-effect transistor when gate-source voltages are changed;

FIG. 9A is a diagram showing dependence of the mobility in the field-effect transistor on amount of SrO, BaO, and Ga₂O₃ added to the IZO;

FIG. 9B is a diagram showing dependence of the hysteresis of the gate-source voltages in the case where the drain currents of the field-effect transistor are 10 nA on amount of SrO, BaO, and Ga₂O₃ added to the IZO;

FIG. 9C is a diagram showing dependence of on-characteristics starting voltages Von in the field-effect transistor on amount of SrO, BaO, and Ga₂O₃ added to the IZO in the case where the voltages at which the sub-threshold slopes S in the field-effect transistor are the minimum (@Smin) are assumed to be the on-characteristics starting voltages Von; and

FIG. 9D is a diagram showing dependence of the sub-threshold slopes S showing the rises of the switching characteristics in the field-effect transistor on amount of SrO, BaO, and Ga₂O₃ added to the IZO.

### NUMERICAL REFERENCES

10 glass substrate
11 gate electrode
12 gate insulator film
13 channel layer
14 source electrode
15 drain electrode
16 passivation film

### BEST MODE FOR CARRYING OUT THE INVENTION

An oxide semiconductor in an Embodiment according to the present invention will be described with reference to the drawings. The oxide semiconductor in this Embodiment is an amorphous oxide semiconductor including: at least one of indium (In), zinc (Zn), and Tin (Sn); at least one of an alkaline metal and/or an alkaline earth metal; and oxygen.

Alkaline metals and alkaline earth metals are chemical elements characterized in that the outermost s-orbit becomes vacant in oxidation state. Alkaline metals and alkaline earth metals can share the s-orbit with In and Zn, which makes it possible to achieve an oxide semiconductor having an excellent electric conductivity. Alkaline metals are the group-I chemical elements including Lithium (Li), Sodium (Na), Potasium (K), Rubidium (Rb), and Cesium (Cs). Alkaline earth metals are the group-II chemical elements including Beryllium (Be), Magnesium (Mg), Calcium (Ca), Strontium (Sr), and Barium (Ba).

Alkaline metals and alkaline earth metals have ionic radius greater than that of Ga, and are elements having ionic radius much different from those of In, Zn, and Sn. Thus, the oxide semiconductor in this Embodiment becomes amorphous more easily than IGZOs.

Most of alkaline metals and alkaline earth metals are chemical elements each having a free energy change of oxidation AG greater than that of Ga (3.8 eV/oxygen atom O). The free energy change of oxidation indicating energy needed for the formation of an oxide at room temperature, that can be translated that energy needed for the reduction process of oxide. Thus, it is unlikely that oxygen is lost from or further combined with another element other than existing bonding in the oxide semiconductor compared with the IGZOs. It is to be noted that a free energy change of oxidation ΔG is represented by the following Expression 1, where ΔH denotes an enthalpy change for the formation of a chemical compound, and ΔS also denotes an entropy change for the formation of a chemical compound.

ΔG=ΔH−TΔS . . . Expression 1

The oxide semiconductor having the above structure can be manufactured according to: one of vapor deposition methods such as the sputtering method, the chemical vapor deposition (CVD) method, the pulsed laser deposition (PLD) method, the atomic layer deposition (ALD) method, the vacuum deposition, and thermal vapor deposition method; or one of wet methods such as the sol-gel method, a method for decomposition from a raw material (precursor) on which no gel process has occured, and the aerogel method.

In the manufacturing according to the sputtering method, PLD method, and thermal vapor deposition method, metals, metal alloys, metal oxides, and oxide compounds are used as target materials.

In the manufacturing according to the CVD method and the wet method, a solution for printing is a solution of a compound of some of the following materials with a desired composition and concentration: metal alkoxide compounds such as methoxide (—OMe), ethoxide (—OEt), N-propoxide (—OPrⁿ), isopropoxide (—OPrⁱ), n-butoxide (—OBuⁿ), s-butoxide (—OBu^{s}), butoxide (—OBuⁱ), and t-butoxide (—OBu^{t}); chelate alkoxides such as methoxy ethanol (—OCH₂CH₂OCH₃) and ethoxy ethanol (—OCH₂CH₂OC₂H₅); hydrides such as organic compounds having a hydroxy group (—OH); and solvents such as alcohol, ethyl, ester, and water. In the manufacturing according to the CVD method, materials having a low vapour pressure among the materials used for such formation according to wet methods are used.

In the formation according to one of the wet methods, one of the following is used as a printing method: ink-jet printing, slit coater printing, screen printing, flexo printing, rotor gravure printing, pad printing, offset printing and so on.

As described above, the oxide semiconductor in this Embodiment includes at least one of an alkaline metal and an alkaline earth metal having an oxygen affinity higher than that of Ga. This makes it possible to provide highly-stable oxide semiconductors which make it possible to achieve devices capable of sufficiently preventing loss of oxygen resulting in prevention of variation or change in device characteristics, and thus having an excellent stability.

In addition, the oxide semiconductor in this Embodiment includes at least one of an alkaline metal and an alkaline earth metal which becomes amorphous more easily than one having just Ga, for example, as a third or fourth element. This makes it possible to provide highly-stable oxide semiconductors having a high uniformity.

### Example

An Example shown below is an application of the oxide semiconductor in this Embodiment.

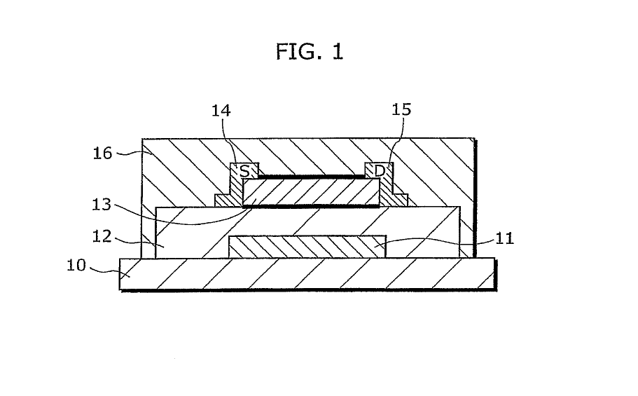

FIG. 1 is a cross-sectional view showing the structure of a field-effect transistor (FET) according to this Embodiment.

This FET is an inverse staggered type (bottom gate type) thin-film transistor (TFT), and includes a glass substrate 10, a gate electrode 11, a gate insulator film 12, a channel layer 13, a source electrode 14, a drain electrode 15, and a passivation film 16.

The gate electrode 11 is formed on the glass substrate 10 and is made of molybdenum (Mo). The gate insulator film 12 is formed on the glass substrate 10 to cover the gate electrode 11, and is made of SiO₂ formed according to the plasma enhanced CVD (PECVD) method.

The channel layer 13 is formed opposite to the gate electrode 11 on the gate insulator film 12, and is made of an oxide semiconductor. The oxide semiconductor is the oxide semiconductor according to this Embodiment, and more specifically, it is either an In—M—Zn—O oxide semiconductor having a composition of In₂O₃, MOₓ, and ZnO (M is at least one of Sr, Ba, Na, K, Rb, and Cs), an Sn—M—Zn—O oxide semiconductor having a composition of SnO₂, MOₓ, and ZnO, or an Sn—M—Sb—O oxide semiconductor having a composition of SnO₂, MOₓ, and SbO. Otherwise, the oxide semiconductor is an In—M—O oxide semiconductor, a Zn—M—O oxide semiconductor, or an Sn—M—O oxide semiconductor which is made of two kinds of metals.

The source electrode 14 and the drain electrode 15 are formed on the channel layer 13, and the passivation film 16 is formed on the glass substrate 10 to cover the gate electrode 11, the gate insulator film 12, the channel layer 13, the source electrode 14, and the drain electrode 15.

The following diagrams show evaluation results of the characteristics of the field-effect transistors (FETs) having the above-mentioned structures.

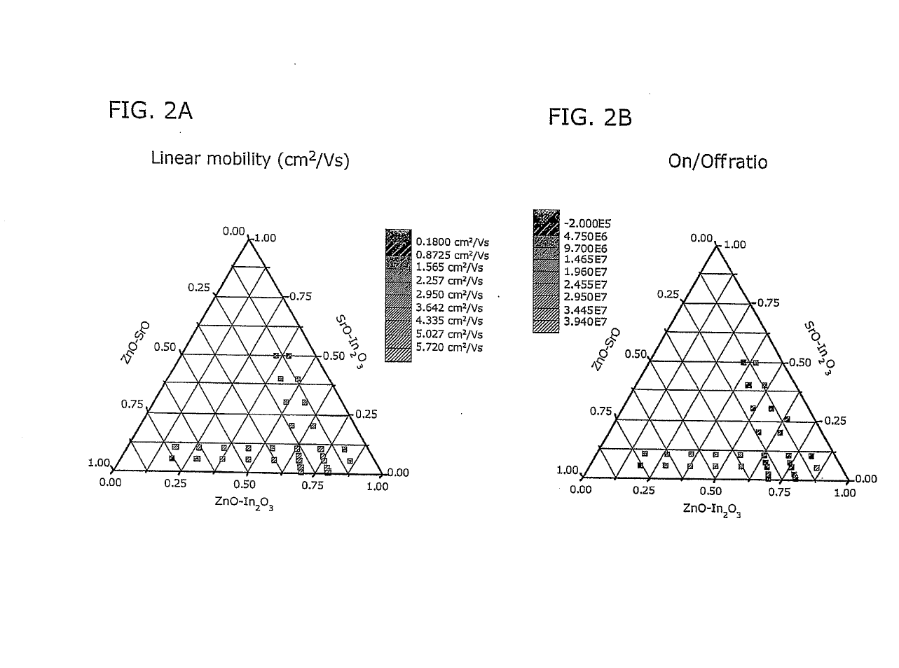

FIG. 2A is a diagram showing variations in the mobility in In—Sr—Zn—O oxide semiconductors, for use as the channel layer, each having a different composition ratio of In₂O₃:SrO:ZnO. In addition, FIG. 2B is a diagram showing a variation in the On/Off ratios of the corresponding field-effect transistors including In—Sr—Zn—O oxide semiconductors, for use as the channel layer, each having a different composition ratio of In₂O₃:SrO:ZnO.

FIG. 2A shows that a mobility of more than 1 cm²/Vs can be obtained in the case where the composition ratio of In₂O₃: ZnO is an oxide molar ratio approximately ranging from 80:20 to 40:60, and that a high mobility can be obtained in the case where the composition ratio of In₂O₃:ZnO is an oxide molar ratio of approximately 70:30. Further, such mobility is increased by two or three times by optimizing the device structure and increasing the film thickness. Since a sufficient mobility can be obtained even in the case of another composition ratio which is not the above-mentioned oxide molar ratios, it is possible to select an oxide molar ratio ranging from 100:0 to 0:100 as the composition ratio of In₂O₃: ZnO, depending on processes and purposes. However, it is to be noted that crystallization is probably induced in oxide semiconductors in many cases when the oxide semiconductors contain approximately 90 to 100 oxide mol percent of In₂O₃ or ZnO, and the resulting grain boundaries may inhibit the electric characteristics. It is to be noted that a mobility of 1 cm₂/Vs is the kind of minimum requirement for a device which requires a current drive for an organic EL or the like (a liquid crystal is driven by voltage).

In addition, FIG. 2A shows that a mobility of more than 1 cm²/Vs can be obtained when the addition amount of SrO is less than 50 oxide mol percent irrespective of the molar ratio of In₂O₃:ZnO. Further, such mobility is increased by two or three times by optimizing the device structure and decreasing (or increasing) the film thickness to reduce intrinsic resistance of the semiconductor film. Accordingly, it is preferable that the amount of SrO added is less than 70 oxide mol percent in an In—Sr—Zn—O oxide semiconductor for use as the channel layer so as to obtain a mobility of 1 cm²/Vs or more. More preferably, the amount of SrO added is less than 50 oxide mol percent as shown in FIG. 2. It is noted that the amount of SrO added must be greater than 0 oxide mol percent in order to ensure stability by adding at least an element having a high oxygen affinity. Likewise, in order to prevent loss of oxygen or further oxidation, one of the equivalent amounts of M can be added to In—M—Zn—O oxide semiconductor, Sn—M—Zn—O oxide semiconductor, In—M—O oxide semiconductor, Zn—M—O oxide semiconductor, Sn—M—Sb—O oxide semiconductor, and Sn—M—O oxide semiconductor.

FIG. 2B shows that 10⁶ or more ON/OFF ratios are obtained in the composition ratios of In₂O₃:SrO:ZnO, and thus that ON/OFF ratios are not affected by the composition ratios.

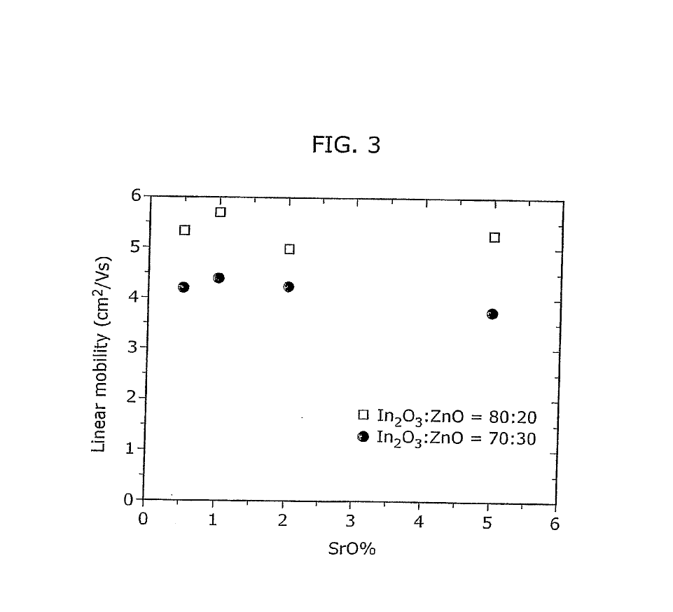

FIG. 3 is a diagram showing variation in the mobility in In—Sr—Zn—O oxide semiconductors (the composition ratios of In₂O₃: ZnO are 80:20 and 70:30) for use as the channel layers each having a different amount of SrO added. In FIG. 3, the vertical axis shows the mobility, and the horizontal axis shows the amount of SrO added.

FIG. 3 shows that a mobility of 1 cm²/Vs or more can be obtained by adding SrO, for example 0.5 oxide mol percent of SrO, irrespective of the composition ratio of In₂O₃:ZnO. Accordingly, it is preferable that the addition amounts of SrO are 0.5 or more oxide mol percent in an In—Sr—Zn—O oxide semiconductor for use as the channel layer so as to ensure a mobility of 1 cm₂/Vs or more.

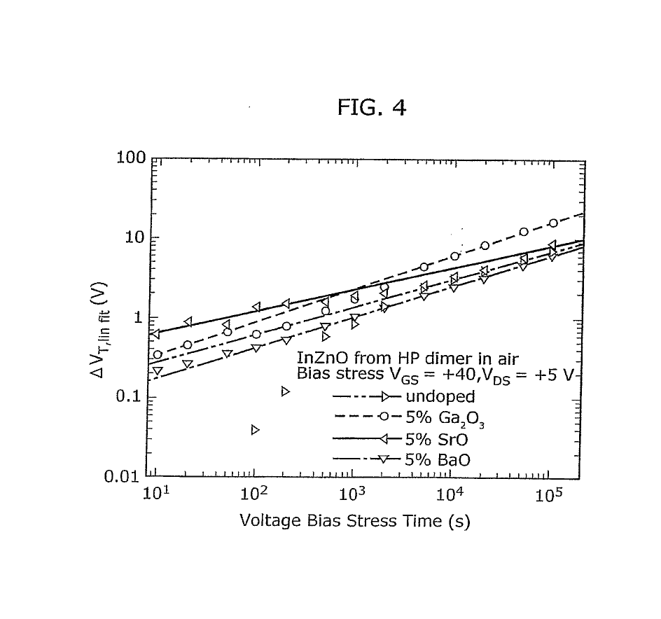

FIG. 4 is a diagram showing variations in the threshold voltage of FETs (samples) each containing a different material in its channel layer. In FIG. 4, the vertical axis shows variation in the threshold voltage obtained according to the following Expression (2), and the horizontal axis shows the total periods of time (stress time) during which 40 V is applied between the gates and sources and 5 V is applied between the sources and drains of the FETs. In Expression (2), V_{G} denotes the applied gate voltage, V_{TO} denotes the initial threshold voltage at the beginning of the bias stress, t denotes the total period of time during which 40 V is applied between the gates and sources and 5 V is applied between the sources and drains of the respective FETs, and TS denotes a time constant. In addition, “undoped” indicates the variation in the threshold voltage of a FET having a channel layer made of an oxide semiconductor (IZO), “5%Ga₂O₃” indicates the variation in the threshold voltage of a FET having a channel layer made of an oxide semiconductor (IZO) containing 5-mol-percent Ga₂O₃, “5%SrO” indicates the variation in the threshold voltage of a FET having a channel layer made of an oxide semiconductor (IZO) containing 5 mol percent of SrO, and “5% BaO” indicates the variation in the threshold voltage of a FET having a channel layer made of an oxide semiconductor (IZO) containing 5 mol percent of BaO.

ΔV_{T}=(V_{G}−V_{TO}) (1-exp (−(t/Tₛ)^{β})) . . . Expression (2)

Table 1 shows values β in the case of the samples, respectively, which have been derived from FIG. 4 and Expression (2). Here, it is shown that values ΔV_{T} indicating change in threshold voltages are smaller as values 13 are smaller. In Table 1, the values β (0.28 and 0.39) of the FETs, in this Example, each having a channel layer made of an IZO added with an alkaline earth metal are smaller than the value β (0.42) of a conventional FET having a channel layer made of an IZO added with Ga. Accordingly, in respect of variations in threshold voltages, it was confirmed that the FETs in this Example have excellent characteristics than the conventional FET.

TABLE 1

| Sample | β |
|---|---|
| Undoped | 0.35 |
| 5% Ga₂O₃ | 0.42 |
| 5% SrO | 0.28 |
| 5% BaO | 0.39 |

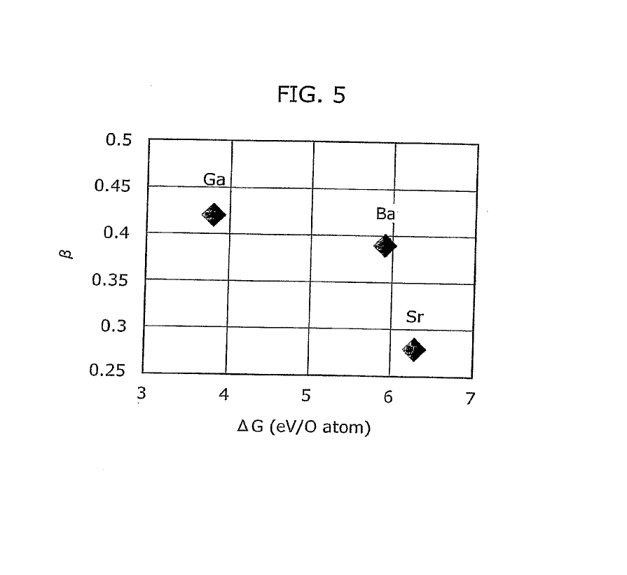

FIG. 5 is a diagram where the vertical axis shows values β indicating the stability of each FET, and the horizontal axis shows values of −ΔG (free energy change for the formation of oxides) having a correlation with oxygen affinity. In FIG. 5, “Ga” shows the sample of “5%Ga₂O₃” in Table 1, “Sr” shows the sample of “5%SrO” in Table 1, and “Ba” shows the sample of “5%BaO” in Table 1.

According to FIG. 5, as the values of −ΔG become greater, that is, the oxygen affinities become greater, the values β become smaller, that is, the stabilities of the FETs increase. Accordingly, in order to keep a small variation in the threshold voltage in a desired FET compared with the conventional FET having a channel layer made of an IGZO, the desired FET has a channel layer made of an IZO added with at least one of an alkaline metal and an alkaline earth metal having a value of −ΔG greater than 3.8 eV/O which is the value of −ΔG in the case of Ga, and preferably, at least one of an alkaline metal and an alkaline earth metal having a value of −ΔG equal to or greater than 5.9 eV/0 which is the value of −ΔG in the case of Ba.

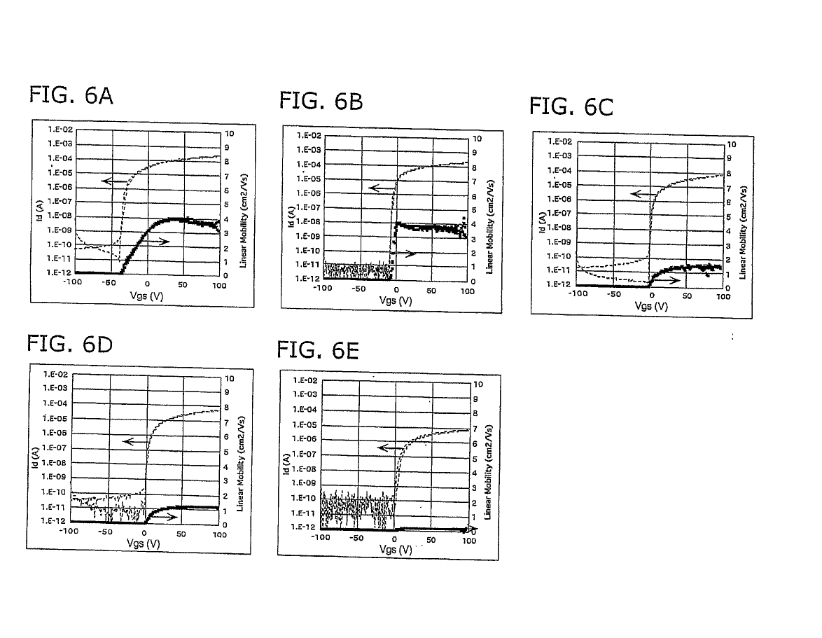

Each of FIG. 6A to FIG. 8 is a diagram showing variations in the values of drain currents and mobility at the time when voltages between the gates and sources are changed and 5 V between the sources and drains of the respective FETs each having a channel layer containing a different material is applied. In each of FIG. 6A to FIG. 8, the left-side vertical axis shows the drain currents, the right-side vertical axis shows the mobility, and the horizontal axis shows the voltages between the gates and sources. In addition, one of the broken lines shows dependence of a drain current on the voltage between the corresponding gate and source in the default state of the FET, and the other one shows the dependence of a drain current on the voltage between the corresponding gate and source in the case where 40 V was applied to the gate and source for a predetermined period of time, and 5 V was applied to the source and drain for a predetermined period of time. In addition, each of the dotted lines shows the dependence of the mobility on the voltage between the corresponding gate and drain in the case where 40 V was applied between the corresponding gate and source for a predetermined period of time and 5 V was applied between the corresponding source and drain for a predetermined period of time.

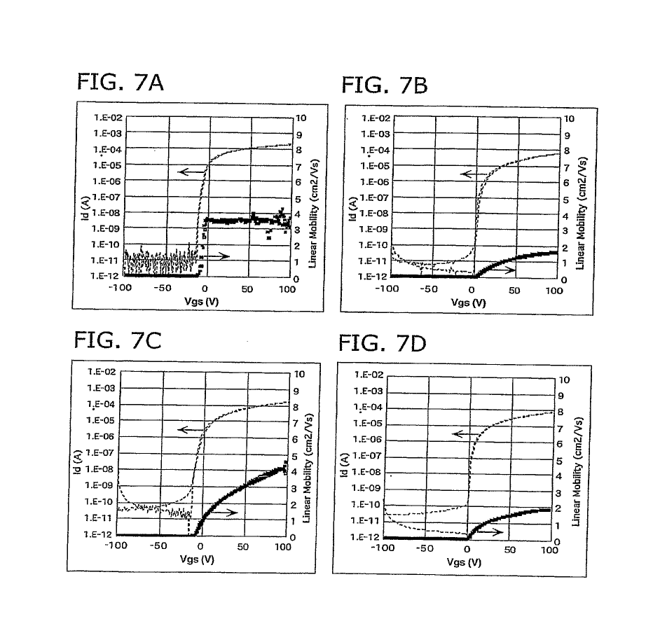

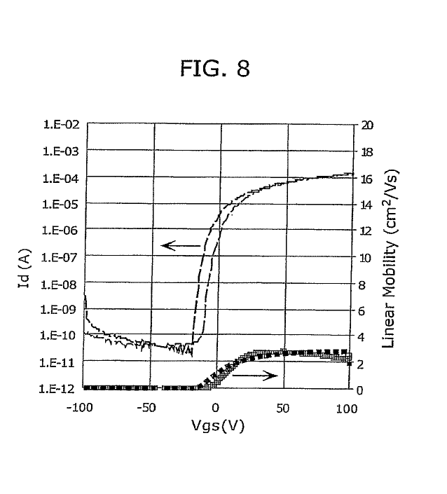

FIG. 6A shows the variation in the characteristics of a FET having a channel layer made of an IZO, more specifically, made of In₂O₃ and ZnO in a oxide molar ratio of 70:30. FIG. 6B shows the variation in the characteristics of a FET having a channel layer made of an IZO containing 1 mol percent of SrO. Likewise, FIGS. 6C, 6D, and 6E show the variations in the characteristics of FETs each having a channel layer made of an IZO containing 5, 10 or 20 mol percent of SrO. In addition, FIGS. 7A and 7B show the variations in the characteristics of FETs each having a channel layer made of an IZO containing 1 or 10 mol percent of Ga₂O₃. Further, FIGS. 7C and 7D show the variations in the characteristics of FETs each having a channel layer made of an IZO containing 1 or 10 mol percent of BaO. Further, FIG. 8 shows the variation in the characteristics of a FET having a channel layer made of In₂O₃ containing 5 mol percent of SrO.

Table 2 shows various values indicating the characteristics of the transistors which have been derived from FIG. 6A to FIG. 8. In Table 2, “undoped” corresponds to the sample of FIG. 6A, “1% SrO” corresponds to the sample of FIG. 6B, “5% SrO” corresponds to the sample of FIG. 6C, “10% SrO” corresponds to the sample of FIG. 6D, “20% SrO” corresponds to the sample of FIG. 6E, “1% Ga₂o₃” corresponds to the sample of FIG. 7A, “10% Ga₂O₃” corresponds to the sample of FIG. 7B, “1% BaO” corresponds to the sample of FIG. 7C, “10% BaO” corresponds to the sample of FIG. 7D, and “5% SrO (In₂O₃)” corresponds to the sample of FIG. 8.

TABLE 2

| | Mobility μ | Threshold | | Von | |
|---|---|---|---|---|---|
| Sample | (cm²/Vs) | voltage Vt | S(min) | (min) | ΔVc |
| Undoped | 3.84 | −14.3 | 0.98 | −37 | 1.25 |
| 1% SrO | 4.41 | 11.8 | 0.76 | −9 | 0.41 |
| 5% SrO | 1.59 | 17.8 | 0.68 | 0 | 0.60 |
| 10% SrO | 1.22 | 14.1 | 0.87 | 0 | 0.40 |
| 20% SrO | 0.26 | 44.3 | 1.61 | 1 | 2.76 |
| 1% Ga₂O₃ | 4.28 | 10.7 | 1.01 | −13 | 0.48 |
| 10% Ga₂O₃ | 1.64 | 32.8 | 0.58 | 0 | 1.31 |
| 1% BaO | 4.52 | 34.6 | 1.18 | −12 | 0.24 |
| 10% BaO | 1.91 | 29.2 | 0.75 | 0 | 0.30 |
| 5% SrO | 2.86 | 11.7 | 1.08 | −45 | −0.06 |
| (In₂O₃) | | | | | |

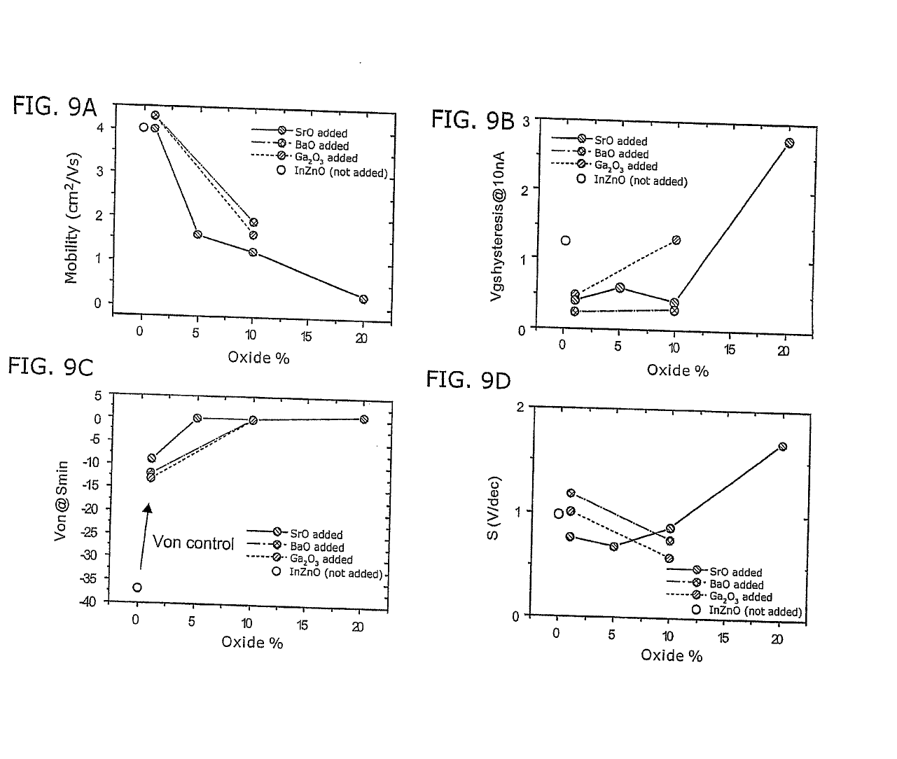

Based on Table 2, FIG. 9A is obtained which shows the mobility dependencies on the addition amounts of SrO, BaO, and Ga₂O₃ respectively added to an IZO. Likewise, FIG. 9B shows the dependencies, of the variation in the voltages between the gates and sources at the time when the drain currents are changed by 10 nA, on the addition amounts of SrO, BaO, and Ga₂O₃ respectively added to the IZO. FIG. 9C shows the dependencies of values Von corresponding to ON voltages indicating On-characteristics on the addition amounts of SrO, BaO, and Ga₂O₃ respectively added to the IZO. FIG. 9D shows the dependency of sub-threshold slopes S on the addition amounts of SrO, BaO, and Ga₂O₃ respectively added to the IZO.

In Table 2, in the case of each FET having a channel layer made of the IZO added with Sr, the gate voltage difference ΔVc is small when a constant current flows in the sub-threshold region and when a gate voltage sweeps −100 V to +100 V and +100 V to −100 V, compared with a FET having a channel layer made of an IZO not added with Sr. Here, ΔVc is considered to be a change in Vt caused by a bias voltage applied in a short period of time during the measurement, and is an indicator of stability as well as ΔVt characteristics. In addition, as for ON voltages Von indicating On characteristics, the drive voltage of an external driving circuit is preferably within a range of −20 V<Von<+20 V, the FET having the channel layer made of the IZO not added with Sr is not suitable for use as having a Von of −37 V, and each of the FETs having a channel layer added with at least one of an alkaline metal or an alkaline earth metal exhibits an excellent characteristics as having a Von within a range of −20 V<Von<+20 V. In addition, as for mobility p, each FET having the channel layer made of the IZO added with Sr keeps 1 cm²/Vs or more. Accordingly, the FET having the channel layer made of the IZO added with Sr has both more stable characteristics and more excellent mobility than the FETs each having the IZO not added with Sr. However, when the amount of Sr added are 20 oxide mol percent or more, the change in critical voltage during the measurement ΔVc of the FET having the channel layer made of the IZO added with Sr is greater than that of the FET having the channel layer made of the IZO not added with Sr, and further, the mobility of the former is less than 1 cm²/Vs. Accordingly, the amount added of an alkaline earth metal in each of the FETs in this Example must be less than 20 oxide mol percent.

Table 2 further shows that the change in critical voltage during the measurement ΔVc in the FET having the channel layer made of the IZO added with Ba is smaller than those of FETs each having the channel layer made of the IZO not added with Ba. Table 2 also shows that the FET having the channel layer made of the IZO added with Ba keeps the mobility μ of 1 cm²/Vs or more. Accordingly, the FET having the channel layer made of the IZO added with Ba has both more stable characteristics and more excellent mobility than the FETs each having the channel layer made of the IZO not added with Ba.

In addition, Table 2 further shows that the change in critical voltage during the measurement ΔVc in the. FET having the channel layer made of the In₂O₃ added with Sr is smaller than those of FETs each having a channel layer made of the IZO not added with Sr. Table 2 also shows that the FET having the channel layer made of the In₂O₃ added with Sr keeps the mobility μ of 1 cm²/Vs or more. Accordingly, the FET having the channel layer made of the In₂O₃ added with Sr has both more stable characteristics and more excellent mobility than the FETs each having the channel layer made of the IZO not added with Sr.

In addition, FIG. 8 shows that the FET having the channel layer made of In₂O₃ added with Sr exhibits fine characteristics without hysteresis. In general, approximately 10 or more oxide mol percent of Ga₂O₃ must be added to In₂O₃ in order to obtain an oxide semiconductor having an amorphous structure by adding Ga₂O₃ to In₂O₃. However, the carrier density decreases with the increase in the addition amounts of Ga₂O₃, which. deteriorates the characteristics of the FET. Accordingly, it is desirable that the addition amounts of Ga₂O₃ are reduced in order not to decrease the carrier density. However, an oxide semiconductor added with approximately 5 mol percent of Ga₂O₃ cannot completely become amorphous, and grain boundaries caused by crystallization probably deteriorate the semiconductor characteristics of the FET. In order to obtain an oxide semiconductor having an amorphous structure and thus has an excellent semiconductor characteristics, it is good to add 5 oxide mol percent of an oxide element having an ionic radius much different from that of In to a semiconductor containing In as a base material. Examples of such elements to be added include: CaO, SrO, and BaO belonging to Group II; and Na₂O, K₂O, RbO, and CsO belonging to Group I.

On the other hand, FIG. 9B shows that the change in critical voltage during the measurement between the gate and source of each FET having a channel layer made of an IZO added with Ba or Sr when the drain current is changed by 10 nA is smaller than those of the FETs each having a channel layers of an IZO oxide semiconductor not added with Ba and Sr. Accordingly, each FET having a channel layer made of an IZO added with Ba or Sr has higher controllability compared to each FET having a channel layer made of an IZO not added with Ba and Sr.

FIG. 9C shows that each FET having a channel layer made of an IZO added with Ba or Sr has a value Von closer to 0 V than that of each FET having a channel layer made of an IZO not added with Ba and Sr. Accordingly, each FET having a channel layer made of an IZO added with Ba or Sr consumes lower power compared to each FET having a channel layer made of an IZO not added with Ba and Sr.

In addition, it is desirable that the sub-threshold slope S (V/dec) which is an indicator of switching characteristics is small. FIG. 9D shows that each IZO added with Sr or Ba has a value of sub-threshold slope S (V/dec) approximately equal to or smaller than that of each IZO not added with Sr and Ba within a range of 10% in the oxide composition, and it is effective to add Sr or Ba.

The following Table 3 shows the mobility of In—Ca—Zn—O oxide semiconductors for use as channel layers each having a different composition ratio of In₂O₃:ZnO and different addition amounts of CaO as shown below. In Table 3, “8:2 +5%” denotes a sample obtained by adding 5 oxide mol percent of CaO to a base material made of In₂O₃ and ZnO in the 80:20 oxide molar ratio. Likewise, “7:3+5%” denotes a sample obtained by adding 5 oxide mol percent of CaO to a base material made of In₂O₃ and ZnO in the 70:30 oxide molar ratio, and “6:4+5%” denotes a sample obtained by adding 5 oxide mol percent of CaO to a base material made of In₂O₃ and ZnO in the 60:40 oxide molar ratio. Likewise, “8:2+10%” denotes a sample obtained by adding 10 oxide mol percent of CaO to a base material made of In₂O₃ and ZnO in the 80:20 oxide molar ratio, “7:3+10%” denotes a sample obtained by adding 10 oxide mol percent of CaO to a base material made of In₂O₃ and ZnO in the 70:30 oxide molar ratio, and “6:4+10%” denotes a sample obtained by adding 10 oxide mol percent of CaO to a base material made of In₂O₃ and ZnO in the 60:40 oxide molar ratio.

TABLE 3

| In2O3:ZnO + | Mobility μ |
|---|---|
| CaO % | (cm²/Vs) |
| 8:2 + 5% | 4.8 |
| 7:3 + 5% | 5.5 |
| 6:4 + 5% | 5.2 |
| 8:2 + 10% | 4.3 |
| 7:3 + 10% | 3.9 |
| 6:4 + 10% | 3.3 |

Table 3 shows that excellent mobility can be obtained irrespective of composition ratios of In₂O₃:ZnO and addition amounts of CaO.

As described above, the FET in this Example is configured to include a channel layer made of an oxide containing: at least one of In, Zn, and Sn; and an alkaline metal and an alkaline earth metal added. This structure enables prevention of loss of oxygen from the channel layer, and thereby preventing change in the carrier density in the channel layer due to such loss of oxygen during the use, resulting in a change in the threshold voltage Vt and the like among the transistor characteristics. Therefore, it becomes possible to achieve FETs having an excellent stability.

Only an exemplary Embodiment of the oxide semiconductor according to the present invention has been described in detail above. However, those skilled in the art will readily appreciate that many modifications are possible in the exemplary Embodiment without materially departing from the novel teachings and advantages of this invention, and therefore, all such modifications are intended to be included within the scope of this invention.

For example, the above Embodiment is described assuming that an oxide semiconductor is used in the channel layer made of FET, but such oxide semiconductor may be used in the electrodes by increasing the carrier density.

### INDUSTRIAL APPLICABILITY

The present invention can be applied to oxide semiconductors, and in particular to field-effect transistors (FETs), and the like.

1-16. (canceled)

17. An amorphous oxide semiconductor comprising:
at least one of indium (In), zinc (Zn), and tin (Sn);
at least one of an alkaline metal and an alkaline earth metal; and
oxygen.

18. The amorphous oxide semiconductor according to claim 17, comprising
both In and Zn.

19. The amorphous oxide semiconductor according to claim 17,
wherein said amorphous oxide semiconductor contains less than 70 mol percent of said at least one of the alkaline metal and the alkaline earth metal.

20. The amorphous oxide semiconductor according to claim 19,
wherein said amorphous oxide semiconductor contains less than 50 mol percent of said at least one of the alkaline metal and the alkaline earth metal.

21. The amorphous oxide semiconductor according to claim 17,
wherein said at least one of the alkaline metal and the alkaline earth metal has an ion radius which is greater than an ion radius of gallium (Ga).

22. The amorphous oxide semiconductor according to claim 17,
wherein a change of free energy for oxide formation in said at least one of the alkaline metal and the alkaline earth metal is more than 3.8 eV/O.

23. The amorphous oxide semiconductor according to claim 17,
wherein a change of free energy for oxide formation in said at least one of the alkaline metal and the alkaline earth metal is 5.9 eV/O or more.

24. The amorphous oxide semiconductor according to claim 17,
wherein the alkaline earth metal is strontium (Sr).

25. The amorphous oxide semiconductor according to claim 17,
wherein the alkaline earth metal is barium (Ba).

26. The amorphous oxide semiconductor according to claim 17,
wherein the alkaline earth metal is calcium (Ca).

27. A field-effect transistor comprising
a channel layer including
an amorphous oxide semiconductor made of:
at least one of indium (In), zinc (Zn), and tin (Sn);
at least one of an alkaline metal and an alkaline earth metal; and
oxygen.

28. A method for manufacturing an amorphous oxide semiconductor, said method comprising
forming, on a substrate, an amorphous oxide semiconductor layer including:
at least one of indium (In), zinc (Zn), and tin (Sn);
at least one of an alkaline metal or an alkaline earth metal; and
oxygen.

29. The method for manufacturing an amorphous oxide semiconductor according to claim 28,
wherein at least one of indium (In), zinc (Zn), and tin (Sn), the alkaline metal or alkaline earth metal is deposited onto the substrate from solution.

30. The method for manufacturing an amorphous oxide semiconductor according to claim 29,
wherein at least one of indium (In), zinc (Zn), and tin (Sn), the alkaline metal or alkaline earth metal is deposited onto the substrate from a solution of a metal alkoxide compound such as metal methoxide (−OMe), ethoxide (−OEt), N-propoxide (−OPrⁿ), isopropoxide (−OPrⁱ), n-butoxide (−OBuⁿ), s-butoxide (−OBu^{s}), i-butoxide (−OBuⁱ), and t-butoxide (−OBu^{t}); a solution of a metal chelate alkoxide such as metal methoxy ethanol (−OCH₂CH₂OCH₃) and ethoxy ethanol (−OCH₂CH₂OC₂H₅); or a solution of a metal hydride such as organic compounds having hydroxyl groups (−OH).

31. The method for manufacturing an amorphous oxide semiconductor according to claim 28,
wherein at least one of indium (In), zinc (Zn), and tin (Sn), the alkaline metal or alkaline earth metal is deposited onto the substrate by vacuum deposition, chemical vapour deposition or atomic layer deposition.

32. An amorphous oxide semiconductor comprising
indium (In), zinc (Zn), an alkaline earth metal, and oxygen,
wherein an addition amount of the alkaline earth metal is less than 20 mol percent.

33. The amorphous oxide semiconductor according to claim 32,
wherein an addition amount of the alkaline earth metal is 1 mol percent or more.

34. The amorphous oxide semiconductor according to claim 33,
wherein the alkaline earth metal is either strontium (Sr) or barium (Ba).

35. An amorphous oxide semiconductor comprising
indium (In), zinc (Zn), an alkaline earth metal of Ca, and oxygen,
wherein a composition ratio of In₂O₃ including the In and ZnO including the Zn is from 6:4 to 8:2 inclusive, and
an addition amount of CaO including the Ca is from 5 to 10 mol percent inclusive.

36. The amorphous oxide semiconductor according to claim 17,
wherein said at least one of the alkaline metal and the alkaline earth metal is strontium (Sr), and
an addition amount of SrO including the Sr is between 0 and 50 mol percent exclusive.

37. The amorphous oxide semiconductor according to claim 36,
wherein an addition amount of the SrO is 0.5 mol percent or more.
